(19) United States
(12) Patent Application Publication
(10) Pub. No.: US 2025/0078585 A1
(43) Pub. Date: Mar. 6, 2025

(54) METHOD OF DIAGNOSING VEHICLE CONSIDERING WEIGHT OF SENSING ELEMENT FOR MOTOR IN VEHICLE AND SYSTEM USING THE SAME

(71) Applicants: SKAIChips Co., Ltd., Suwon-si (KR); Research & Business Foundation SUNGKYUNKWAN UNIVERSITY, Suwon-si (KR)

(72) Inventors: Kang Yoon LEE, Seoul (KR); Dae Young CHOI, Suwon-si (KR); Dong Gyun KIM, Suwon-si (KR); Jong Wan JO, Suwon-si (KR)

(73) Assignees: SKAIChips Co., Ltd., Suwon-si (KR); Research & Business Foundation SUNGKYUNKWAN UNIVERSITY, Suwon-si (KR)

(21) Appl. No.: 18/810,695

(22) Filed: Aug. 21, 2024

(30) Foreign Application Priority Data
Aug. 29, 2023 (KR) 10-2023-0113695

(51) Int. Cl. G07C 5/08; G01R 31/34

(52) U.S. Cl. CPC G07C 5/0808; G01R 31/343; G07C 5/0816; G07C 5/085

(57) ABSTRACT

Disclosed is a method of diagnosing a vehicle including an electric motor performed in the vehicle. The method includes acquiring first to third measurement values for a temperature, a voltage, and a current associated with the electric motor from one or more sensors installed for the electric motor, calculating first to third scores for a predetermined diagnostic factor based on each of the first to third measurement values, reading a weight for each of the temperature, the voltage, and the current with regard to the predetermined diagnostic factor from a database installed in the vehicle, and calculating a comprehensive diagnostic score for the predetermined diagnostic factor based on the weight for each of the first to third scores and the predetermined diagnostic factor.

### CROSS-REFERENCE TO RELATED APPLICATION(S)

This application claims priority from Korean Patent Application No. 10-2023-0113695, filed on Aug. 29, 2023, in the Korean Intellectual Property Office, the disclosure of which is incorporated herein by reference in its entirety.

### BACKGROUND OF THE INVENTION

### Field of the Invention

The present disclosure relates to a method of evaluating various diagnostic factors, such as whether failure occurs in a motor of a vehicle including an electric motor, such as an electric vehicle or a hybrid vehicle, and a system for performing such a method.

### Description of the Related Art

Technology for diagnosing a state of a driving system and predicting failure in advance is referred to as PHM (Prognostic and health management). PHM has already been applied to automobiles. However, PHM has merely been used to transmit data from a failure diagnosis center to an external cloud server through a network for analysis, and has never been implemented on a single chip inside an automobile.

In other words, rather than diagnosing a state of a driving system of an automobile using an internal system (SoC) of the automobile, the state of the automobile has been diagnosed through an external server. Accordingly, there have been problems that linkage to an external server through a network is necessary, and real-time diagnosis may be difficult.

To solve the above problems, the present inventor proposes a method of determining whether failure occurs in a motor in a vehicle, and a system using the same.

### SUMMARY OF THE INVENTION

The present disclosure may have the following objects.

It is another object of the present disclosure to provide a method and system for diagnosing a state and failure of a motor, etc. in a vehicle through a diagnostic system located in the vehicle.

It is a further object of the present invention to provide a method and system for monitoring a state of a driving system in a vehicle in real time using artificial intelligence (AI) technology.

It is a further object of the present invention to provide a method and system for individually and/or comprehensively considering various diagnostic factors when predicting whether failure occurs in a driving system in a vehicle.

The problems to be solved through various embodiments of the present disclosure are not limited to the problems mentioned herein, and other problems not mentioned herein will be clearly understood by those skilled in the art from the description below.

According to some embodiments of the present disclosure, a method of diagnosing a vehicle is presented. The method of diagnosing the vehicle is performed in the vehicle including an electric motor. The method of diagnosing the vehicle may include acquiring a first measurement value for a temperature associated with the electric motor, a second measurement value for a voltage associated with the electric motor, and a third measurement value for a current associated with the electric motor from one or more sensors installed in the electric motor, calculating a first score for a predetermined diagnostic factor based on the first measurement value, calculating a second score for the predetermined diagnostic factor based on the second measurement value, calculating a third score for the predetermined diagnostic factor based on the third measurement value, reading a weight for each of the temperature, the voltage, and the current with regard to the predetermined diagnostic factor from a database installed in the vehicle, and calculating a comprehensive diagnostic score for the predetermined diagnostic factor based on the weight for each of the first score, the second score, the third score, and the predetermined diagnostic factor.

In some examples, at least one of the first score, the second score, or the third score may be calculated based on at least one of a measurement value, a variance value, and a standard deviation value from a sensor.

In some examples, the method may further include updating the weight for the predetermined diagnostic factor at predetermined time intervals. The calculating a comprehensive diagnostic score may include recalculating the comprehensive diagnostic score in response to weight update.

In some examples, the method may further include comparing at least one of the first score, the second score, the third score, or the comprehensive diagnostic score calculated for the predetermined diagnostic factor with a corresponding reference value pre-stored in the database, and generating a warning based on a comparison result.

In some examples, the predetermined diagnostic factor may be one or more diagnostic factors. In these examples, the reading may include reading three weights for the temperature, the voltage, and the current for each diagnostic factor, and the calculating may include calculating the first score, the second score, the third score, and the comprehensive diagnostic score for each diagnostic factor.

In some examples, the method may further include evaluating at least one of a state, failure, stability, or expected failure of the electric motor based on the comprehensive diagnostic score. In these examples, the predetermined diagnostic factor may correspond to at least one of the state, failure, stability, or expected failure of the electric motor. In these examples, the evaluating may be performed using an AI module installed in the vehicle.

In some examples, the method may be performed by an operation of a System on Chip (SoC) installed in the vehicle.

In some embodiments, a vehicle diagnostic system performing the method of diagnosing the vehicle is presented. The illustrative vehicle diagnostic system may be installed in a vehicle including an electric motor. The vehicle diagnostic system may include a sensor unit, a database, and one or more processors. The sensor unit may include a plurality of sensors configured to measure a temperature associated with the electric motor, a voltage associated with the electric motor, and a current associated with the electric motor. The database may store a weight for the temperature, a weight for the voltage, and a weight for the current with regard to a predetermined diagnostic factor.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a block diagram illustrating a schematic configuration of an illustrative vehicle diagnostic system according to some embodiments of the present disclosure;

FIG. 2 is a diagram illustrating some configurations of an illustrative vehicle diagnostic system according to some embodiments of the present disclosure;

FIG. 3 is a flowchart illustrating an illustrative process of diagnosing a vehicle according to some embodiments of the present disclosure;

FIG. 4 is a diagram illustrating a process of training an AI module according to an embodiment of the present disclosure; and

FIG. 5 is a diagram illustrating an example of reading and updating weights according to some embodiments of the present disclosure.

### DETAILED DESCRIPTION OF THE INVENTION

Hereinafter, embodiments will be described in detail with reference to the attached drawings. However, since various changes may be made to the embodiments, the scope of rights of the patent application is not limited or restricted by these embodiments. It should be understood that all changes, equivalents, or substitutes for the embodiments are included in the scope of rights.

The terms used in the embodiments are for descriptive purposes only and should not be construed as limiting. A singular expression includes the plural form unless the context clearly dictates otherwise. In the present specification, it should be understood that a term such as “include” or “have” is intended to designate that the features, numbers, steps, operations, elements, parts, or combinations thereof described in the specification are present, and does not preclude the possibility of addition or presence of one or more other features, numbers, steps, operations, elements, parts, or combinations thereof.

Unless otherwise defined, all terms used herein, including technical or scientific terms, have the same meanings as those generally understood by a person of ordinary skill in the technical field to which the embodiments pertain. Terms defined in commonly used dictionaries should be interpreted as having meanings consistent with the meanings in the context of the related technology, and should not be interpreted in an ideal or excessively formal sense unless explicitly defined in the present application.

In addition, in description with reference to the accompanying drawings, identical components will be assigned the same reference symbols, and overlapping descriptions thereof will be omitted. In description of an embodiment, when it is determined that a detailed description of related known technology may unnecessarily obscure the gist of the embodiment, the detailed description will be omitted.

Further, in describing the components of the embodiment, terms such as first, second, A, B, (a), and (b) may be used. These terms are only used to distinguish one component from other components, and the nature, order, or sequence of the component is not limited by the term. When a component is described as being “linked to”, “combined with”, or “connected to” another component, the component may be directly linked or connected to another component. However, it should be understood that another component may be “linked”, “combined”, or “connected” between the respective components.

A component included in one embodiment and a component having a common function will be described using the same name in another embodiment. Unless stated to the contrary, a description given in one embodiment may be applied to other embodiments, and detailed description will be omitted to the extent of overlap.

Hereinafter, to enable those skilled in the art to easily practice the present invention, preferred embodiments of the present invention will be described in detail with reference to the attached drawings.

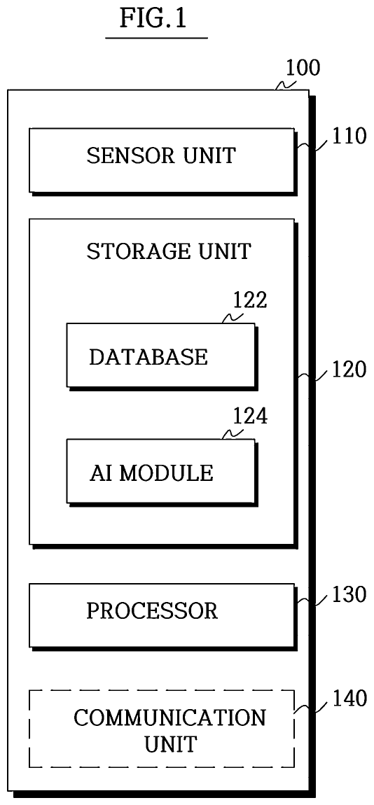

FIG. 1 is a block diagram illustrating a schematic configuration of an illustrative vehicle diagnostic system 100 according to some embodiments of the present disclosure. As illustrated in FIG. 1, the vehicle diagnostic system 100 may include a sensor unit 110, a storage unit 120, and a processor 130. In an additional embodiment, the vehicle diagnostic system 100 may further include a communication unit 140. The vehicle diagnostic system 100 is a system installed inside a vehicle, and diagnoses an operating state, whether failure occurs, etc. for an electric motor or an internal device associated with the electric motor, for example, an actuator or a battery, in a vehicle including the electric motor such as a hybrid vehicle or an electric vehicle. At least a part of the vehicle diagnostic system 100 is implemented in the form of a System on Chip (SoC) and may perform various functions.

The sensor unit 110 may measure a temperature of the electric motor, a voltage associated with the electric motor, and a current associated with the electric motor. Accordingly, the sensor unit 110 may include at least one temperature sensor, one or more voltage sensors, and one or more current sensors. In this regard, the sensor unit 110 may include a plurality of sensors, for example, at least three sensors. The sensors of the sensor unit 110 may be installed at locations associated with the electric motor.

The storage unit 120 may store a measurement value measured by the sensor unit 110. In addition, as illustrated in FIG. 1, the storage unit 120 may include a database 122 and an AI module 124. The database 122 may store and manage data for diagnosing states of driving elements of the vehicle, for example, the electric motor and the actuator. In some examples, the database 122 may store a relative weight of each of temperature, voltage, and current. The AI module 124 may store an AI algorithm including at least some of an artificial neural network algorithm, a blockchain algorithm, a deep learning algorithm, a mechanism related thereto, an operator, a language model, and big data for processing operations performed by the vehicle diagnostic system 100, such as data sensing, failure factor extraction, cluster generation, linear classification, and/or Gaussian classification according to the present disclosure.

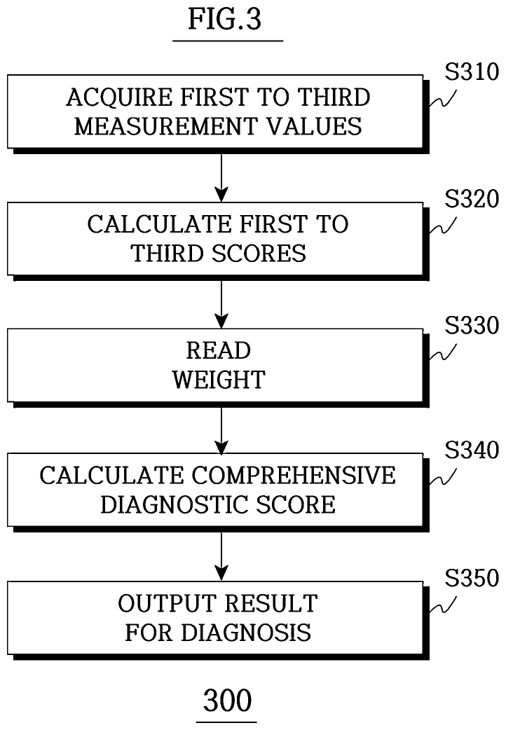

The processor 130 may include one or more processors. In some examples, the processor 130 may include a separate processor, for example, a graphics processing unit (GPU), to drive the AI module 124. The processor 130 may execute a program stored in the storage unit 120 to perform vehicle diagnosis according to the present disclosure. An illustrative vehicle diagnostic process according to the present disclosure performed by the processor 130 is described in detail in an example of FIG. 3.

In some additional examples, the communication unit 140 may be configured to communicate with the exterior of the vehicle and may be used to update data in the database 122 and/or the AI module 124. The communication unit 140 may be implemented using various communication technologies. That is, it is possible to apply Wi-Fi, WCDMA (Wideband CDMA), HSDPA (High Speed Downlink Packet Access), HSUPA (High Speed Uplink Packet Access), HSPA (High Speed Packet Access), Mobile WiMAX, WiBro, LTE (Long Term Evolution), 5G, 6G, Bluetooth, IrDA (infrared data association), NFC (Near Field Communication), Zigbee, wireless LAN technology, etc. In addition, when a service is provided through connection to the Internet, TCP/IP, which is a standard protocol for information transmission on the Internet, may be employed.

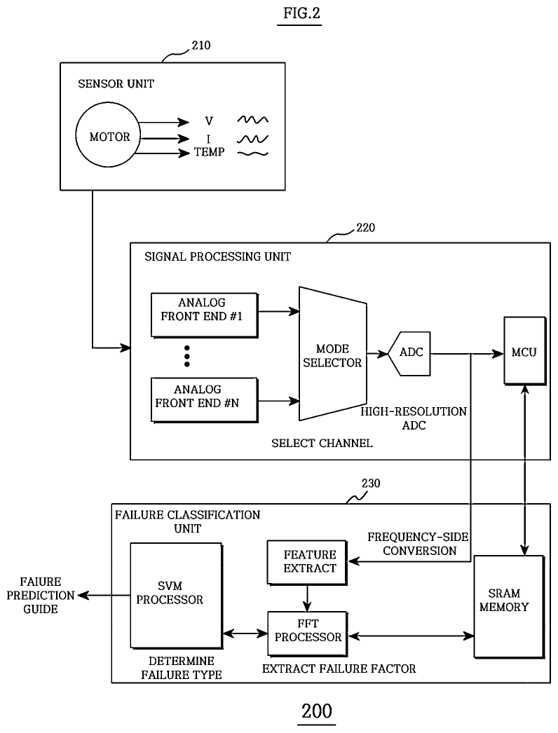

FIG. 2 is a diagram illustrating some configurations of an illustrative vehicle diagnostic system 200 according to some embodiments of the present disclosure. The vehicle diagnostic system 200 illustrated in FIG. 2 represents a configuration from the perspective of signal processing as an example of the vehicle diagnostic system of FIG. 1. The vehicle diagnostic system 200 may include a sensor unit 210, a signal processing unit 220, and a failure classification unit 230. The sensor unit 210 may sense a state of at least one motor in the vehicle and acquire a sensing value, that is, a measurement value. Here, the sensor unit 210 may measure a temperature (Temp), a voltage (V), and a current (I) of the motor using various sensors. The acquired temperature, voltage, and current of the motor may be analog values, as illustrated in FIG. 2.

Measurement values measured by the sensor unit 210 may be transmitted to the signal processing unit 220. The signal processing unit 220 may include a plurality of AFEs (Analog Front Ends), a mode selector, an ADC (Analog Digital Converter), an MCU, etc. In some examples, the measurement values (temperature, voltage, and current in analog forms) acquired through the sensor unit 210 may be transmitted to the ADC through several AFEs and converted into digital forms. Here, the temperature, the voltage, and the current, which are the measurement values, may be transmitted through different AFEs, respectively, and may each pass through an amplifier, a filter, etc.

The measurement values (temperature, voltage, and current) converted into the digital forms may be transmitted to the failure classification unit 230. The failure classification unit 230 may include an SVM processor, an FFT processor, and an SRAM as illustrated in FIG. 2. The measurement values in the digital forms transmitted to the failure classification unit 230 may be extracted as feature values through an AI module (not illustrated) after passing through the FFT processor, etc. In some embodiments according to the present disclosure, the feature values are diagnostic scores for each of temperature, voltage, and current, for example, first to third scores and a comprehensive diagnostic score which is a combination thereof. According to some embodiments of the present disclosure, these first to third scores and the comprehensive diagnostic score are derived through the AI module, etc. Here, the AI module may be included in the failure classification unit 320, and may be present as a separate module on a chip of the vehicle diagnostic system 100 in some cases.

The feature values may be extracted by referring to an operation formula {Ax+By+Cz+D=feature value (A, B, C, and D are variables (parameters), x is a conversion value related to the measured temperature, y is a conversion value related to the sensed voltage, and z is a conversion value related to the sensed current)}, and the AI module may refer to the above-described formula. When temperature, voltage, current, etc. are measured for each time zone, the feature values may also be extracted for each time zone and implemented as a two-dimensional graph (x-axis: time, y-axis: feature values). The above-described formula may vary depending on the settings.

That is, the feature values extracted from the measurement values may represent the state of the corresponding motor in stages. That is, when the state of the vehicle motor is represented as a normal state or an abnormal state, the feature values include information capable of dividing the respective states into a plurality of stages. In this way, it is possible to determine a predetermined period of time in which failure of the motor is expected and/or a point in time of failure.

FIG. 3 is a flowchart illustrating an illustrative process 300 of diagnosing the vehicle according to some embodiments of the present disclosure. The process 300 of FIG. 3 may be performed in a computing device illustrated in the vehicle diagnostic system 100 of FIG. 1 and the vehicle diagnostic system 200 of FIG. 2. Accordingly, a computing device illustrated in FIG. 3 is installed in the vehicle, and content described with respect to FIGS. 1 and 2 may also be applied to a description of FIG. 3.

The process 300 illustrated in FIG. 3 may include one or more operations, functions, or actions, as illustrated by blocks S310, S320, S330, S340, and/or S350. Meanwhile, the schematic operations illustrated in FIG. 3 are provided only as examples, and some of the operations may be optional, fewer operations may be combined, or the operations may be expanded to additional operations, without departing from the essence of the disclosed embodiment. In addition, even though respective blocks S310, S320, S330, S340, and S350 of the process 300 are illustrated as being sequential, in an actual implementation, the blocks may be performed simultaneously, in parallel, or in a different order.

The process 300 may start from block S310 of “acquiring first to third measurement values.” In block S310, the computing device may acquire a first measurement value for a temperature of the electric motor, a second measurement value for a voltage associated with the electric motor, and a third measurement value for a current associated with the electric motor from one or more sensors installed for the electric motor. The measurement values acquired by the computing device from the sensors may be analog values, and appropriate signal processing may be performed on these analog values to convert the analog values into data in a digital form. The process 300 may proceed from block S310 to block S320 of “calculating first to third scores”.

In block S320, the computing device may calculate diagnostic scores for the temperature, the voltage, and the current, respectively. Theses diagnostic score may be related to predetermined diagnostic factors, and the predetermined diagnostic factors may be related to, for example, whether failure occurs in the electric motor, a state, stability, and failure prediction value of the electric motor, a state and stability of a battery supplying power to the electric motor, etc. The computing device may calculate a first score based on a first measurement value acquired in block S310, calculate a second score based on a second measurement value, and calculate a third score based on a third measurement value. The first to third scores may be calculated using various calculation methods. Each of the first to third scores may be obtained from the measurement values thereof. However, without being limited thereto, each of the first to third scores may be calculated based on at least one of the measurement values, an average value of the measurement values, or a variance value and a deviation value of the measurement values or a combination thereof. In one example, the computing device may compare a predetermined diagnostic factor (for example, whether failure occurs) and a current measurement value (for example, a first measurement value) with a predetermined value (for example, 60 degrees or −7 degrees as a failure criterion of the electric motor), and assign a lower score as a difference therebetween decreases. In another example, for a plurality of diagnostic factors (for example, whether failure occurs in the electric motor and stability of the electric motor), the computing device may evaluate a current measurement value (for example, the first measurement value) based on two criteria (for example, greater than 60 degrees and less than or equal to −7 degrees as a failure criterion and an appropriate range of 20 to 30 degrees). In still another example, when there are several sensors for a single measurement value (for example, a second measurement value), a reference value may be set for each of measurement values from the sensors (for example, a different voltage reference value such as 12V, 24V, 90V, or 180V may be set for each voltage measurement portion of the motor). In yet another example, the computing device may continuously collect measurement values from the sensor units and continuously calculate an average of the measurement values. The computing device may indicate a score for evaluating a degree to which a temperature, a voltage, or a current corresponds to a normal operating range through a variance value and a standard deviation value indicating a degree to which a currently acquired measurement value deviates from an average value.

Calculation of the first to third scores may be performed in real time or at predetermined time intervals. In some embodiments, the number of predetermined diagnostic factors may be one or more, and when there are two or more factors to be diagnosed, the first to third scores may be calculated for each diagnostic factor. Each score may be calculated by the computing device using the AI module and may be calculated using a calculation method learned by the AI module. The calculation method for each score stored in the AI module may be learned using training data.

In some examples, calculation of the first to third scores may be based on a situation of the vehicle. It may be assumed that the vehicle is divided into a plurality of classes based on the situation of the vehicle. The plurality of classes may include a first class, a second class, etc. Here, the situation of the vehicle may include model year of the vehicle, an ambient temperature of the vehicle, etc. For example, a vehicle that is 5 or more years old may be in the first class and a vehicle that is less than 5 years old may be in the second class, or a vehicle having an ambient temperature of 20 degrees or higher may be in the first class and a vehicle having an ambient temperature of below 20 degrees may be in the second class. It is obvious that the plurality of classes is not limited to the first class and the second class, and other additional classes (for example, a third class, a fourth class, etc.) may be present. Further, the situation of the vehicle may include other factors in addition to model year of the vehicle and ambient temperature of the vehicle.

In addition, it may be assumed that a customized reference value is set for each class and for each temperature, voltage and current. Here, the customized reference value is compared with the first to third calculated scores, and may be a criterion for determining whether the motor, etc. (driving system) is in a safe state or a failure state. The process 300 may proceed from block S320 to block S330 of “reading weights.”

In block S330, the computing device may read weights for each of temperature, voltage, and current, that is, three weights, from the database with respect to a predetermined diagnostic factor. The database may be installed in the vehicle. The computing device, such as the AI module and/or a communication module, may update the weights stored in the database at predetermined time intervals. In some examples, the computing device may read the weights again in response to the weights being updated. The process 300 may continue from block S330 to block S340 of “computing a comprehensive diagnostic score.”

In block S340, the computing device may calculate a comprehensive diagnostic score based on the first to third scores calculated in block S320 and the weights read in block S330. The comprehensive diagnostic score may be calculated for each diagnostic factor. In some examples, when the weights are updated by the AI module and/or the communication module, the computing device may recalculate the comprehensive diagnostic score in response thereto. For example, the comprehensive diagnostic score may be calculated as a sum of the products of the respective weights and the corresponding scores. However, a calculation method is not limited thereto, and various calculation methods may be used. The process 300 may continue from block S340 to block S350 of “outputting a result for diagnosis.”

In block S350, the computing device may determine and output a useful result for a predetermined diagnostic factor based on at least one of comprehensive diagnostic scores. The first to third scores and the comprehensive diagnostic score may represent information allowing determination of various states of the electric motor of the vehicle, and the computing device may determine the state of the motor using a calculated value. In some examples in which a predetermined diagnostic factor is failure, the computing device may determine that the motor is either in the safe state, the failure state, etc., based on the comprehensive diagnostic score. In some examples in which the predetermined diagnostic factor is a failure-predicted state, the computing device may determine, based on the comprehensive diagnostic score, whether the electric motor is in a state in which failure is expected to occur within a predetermined period of time (for example, one year) or is in the safe state. In some examples in which the predetermined diagnostic factor is stability, the computing device may determine whether a general operation of the electric motor is stable or unstable based on the comprehensive diagnostic score. Results of diagnosis may be implemented by combining the above-described factors.

In some examples, the computing device may evaluate various factors of the electric motor based on the comprehensive diagnostic score. In some examples, some of the first to third scores may additionally be used in this evaluation. By using the comprehensive diagnostic score, and the first to third scores for temperature, voltage, and current together, it is possible to further subdivide the results of diagnosis.

In addition, the above-described determination and evaluation may be performed by comparing the comprehensive diagnostic score to a reference value. In some examples, the computing device may compare at least one of the first score, the second score, the third score, and the comprehensive diagnostic score calculated for a predetermined diagnostic factor with a corresponding reference value pre-stored in the database, and output a result value in advance according to a result of the comparison. In this example, when the comparison result exceeds a predetermined amount, there may be a problem with the electric motor, and thus a warning may be generated.

In some examples, for example, two or more reference values (for example, p and q) may be preset, and the safe state, the failure-predicted state, and the failure state may be determined based on the reference values and the comprehensive diagnostic score. The installed motor may be determined to be in the safe state when the comprehensive diagnostic score is less than or equal to the reference value p, determined to be in the failure-predicted state when the comprehensive diagnostic score is greater than the reference value p and less than or equal to the reference value q, and determined to be in the failure state when the comprehensive diagnostic score is greater than the reference value q.

Here, the computing device may set the above reference values using the trained AI module. In other words, it is possible to repeatedly perform a training process in which data acquired from a measurement value such as the temperature of the vehicle, an extracted feature value, and feature values undergoing processing such as normalization are processed, and then a reference value for distinguishing each state boundary of the motor is extracted while passing the values through the AI module. It is obvious that the reference values may be arbitrarily set without passing through the trained AI module, etc.

In some examples, the computing device may determine a predetermined period of time during which motor failure is expected to occur in units of days, weeks, months, and/or years based on data stored in an updated database. The computing device may further consider an additional factor in addition to the first through third scores and the comprehensive diagnostic score, in determining the period of time during which failure is expected. In some examples, the computing device may determine a certain period of time during which failure of the motor is expected further based on the model year (or class), mileage, etc. of the vehicle.

Upon determining the failure state or the failure-predicted state of the motor, the computing device may determine a time to inspect (for example, repair or replace) the motor based on a predetermined period of time.

In this instance, the computing device may determine a motor inspection time and/or shorten or extend the predetermined period of time in units of days, weeks, and/or months based on class of the vehicle, a function of the motor, and feature values included in a cluster in a failure state, and may determine that urgent inspection is necessary when the inspection time is within a designated period.

In one example, in a state in which urgent inspection is necessary when the vehicle is a first class vehicle, the motor is a motor related to driving of the vehicle, and a predetermined period in which failure of the motor is expected satisfies a condition of within one week, the computing device may determine that urgent inspection of the motor is necessary when the vehicle is the first class, there is no history of repair or replacement of the motor, the state of the motor related to regenerative braking is a failure state, and a predetermined period in which failure of the motor is expected is three days based on a feature value included in a cluster in a failure state.

In another example, when the vehicle is a frequently used vehicle or a vehicle with which safety issues need to be more strictly considered (for example, taxi, kindergarten bus, etc.), the computing device may set three or more reference values in advance and determine the state of the installed motor as a normal state, a state in which failure is expected within six months, a state in which failure is expected within three years, a failure state, etc. In other words, a specific predetermined period may be determined in more detail as the state of the motor.

As described above, the computing device may generate a guidance message including a checked state of the motor and/or a predetermined period during which failure of the motor is expected, and store the guidance message in a storage unit of the vehicle or output the guidance message through a display and/or a speaker.

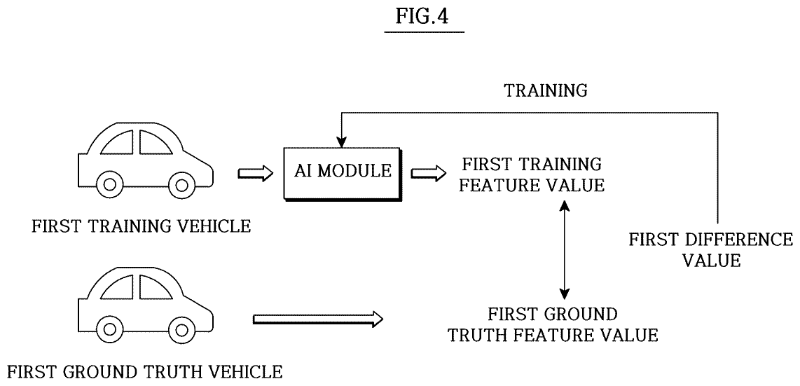

FIG. 4 is a diagram illustrating a process of training the AI module according to an embodiment of the present disclosure. Hereinafter, an illustrative training process of the AI module that extracts feature values such as the first to third scores and the comprehensive diagnostic score from the measurement values from the sensor will be examined with reference to FIG. 4.

First, to train the AI module, it may be assumed that a plurality of vehicles for training is divided into matching classes (for example, first class, second class, etc.) based on each situation (for example, model year and ambient temperature).

Next, the computing device such as the vehicle diagnostic system 100 of FIG. 1 and the vehicle diagnostic system 200 of FIG. 2 may use the AI module to extract first training feature values from a plurality of first training vehicles included in the first class. Further, the computing device may acquire a first ground truth feature value from a ground truth vehicle included in the first class.

Here, the first ground truth feature value may correspond to a value representing an actual state of the ground truth vehicle (abnormal or normal state confirmed from temperature, voltage, and current). The actual ground truth vehicle corresponds to a vehicle for which abnormality has already been recognized, and accordingly, the first ground truth feature value may be specified as a value smaller than the reference value (for example, when the reference value is preset to 10, the first ground truth feature value is specified as one of numbers less than or equal to 10).

Further, the computing device may acquire a first difference value by comparing the first ground truth feature value with the first training feature value, and update a parameter of the AI module based on the first difference value. That is, the computing device may perform a process of checking a difference between the first ground truth feature value and the first training feature value and updating a parameter of the AI module so that there is no difference (so that the first training feature value is the same as the first ground truth feature value). Such a process of updating the parameter of the AI module may be repeated, and as the number of repetitions increases, more accurate determination (feature value extraction) of the AI module may be possible.

Further, as in the first class, the computing device may extract a second training feature value from a plurality of second training vehicles included in the second class using the AI module.

Further, the computing device may acquire a second ground truth feature value from the ground truth vehicle included in the second class, and acquire a second difference value by comparing the value with the second training feature value. Further, it is possible to perform a process of updating the parameter of the AI module based on the second difference value.

As described above, the parameter of the AI module may be repeatedly updated using the training vehicle and the ground truth vehicle for each of the first class and the second class, and the AI module may be trained in this way.

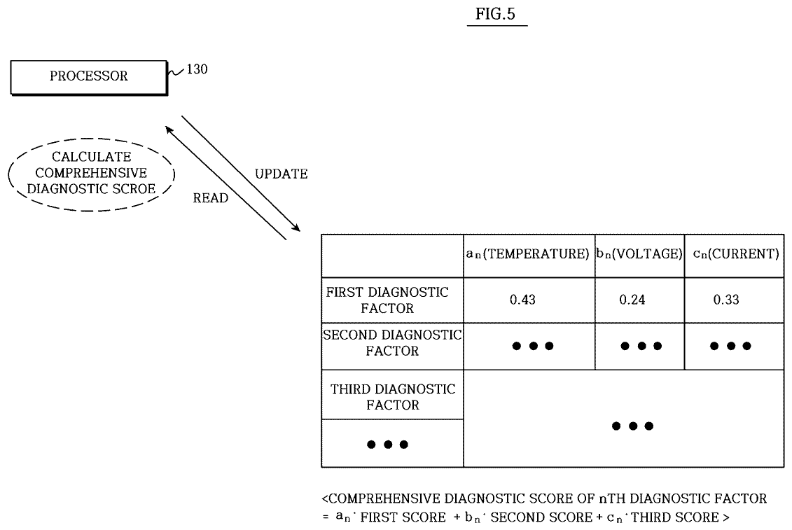

FIG. 5 is a diagram illustrating an example of reading and updating weights according to some embodiments of the present disclosure. A computing element such as the processor 130 of the vehicle diagnostic system 100 of FIG. 1, for example, the AI module and the vehicle diagnostic system 200 of FIG. 2 reads and updates weights for a temperature, a voltage, and a current stored in the database for each diagnostic factor. The computing element calculates a comprehensive diagnostic score for a predetermined diagnostic factor based on the read weights and the first to third scores described above.

In this way, according to the present disclosure, the following effects are achieved.

According to various embodiments of the present disclosure, there is an effect of being able to diagnose a state of the motor, etc. in the vehicle through a diagnostic system installed in the vehicle, for example, SoC, and verify not only whether there is failure but also an expected period until failure.

Further, according to various embodiments of the present disclosure, it is possible to more accurately classify a state of the vehicle, especially the electric motor, by calculating evaluation scores for each of a temperature, a voltage, and a current, which may affect various diagnostic factors such as failure and state of the electric motor, and calculating a score combining these evaluation scores.

As described above, by monitoring the state of the driving system in the vehicle in real time using AI technology, there is an effect of being able to predict a state of the motor more accurately through training of the AI module.

The embodiments according to the present invention described above may be implemented in the form of program instructions executable through various computer components and recorded on a computer-readable recording medium. The computer-readable recording medium may include program instructions, data files, data structures, etc., singly or in combination. The program instructions recorded on the computer-readable recording medium may be specially designed and configured for the present invention or may be known and usable by those skilled in the computer software field. Examples of the computer-readable recording medium include hardware devices specially configured to store and perform program instructions, such as a hard disk, a ROM, and a RAM. Examples of the program instructions include not only machine language code such as that created by a compiler, but also high-level language code executable by a computer using an interpreter, etc. A hardware device may be configured to operate as one or more software modules to perform processing according to the invention, and vice versa.

The present invention has been described above using specific details such as specific components and limited embodiments and drawings. However, this is only provided to facilitate a more general understanding of the present invention, and the present invention is not limited to the embodiments. Anyone skilled in the art to which the present invention pertains may make various modifications and variations from this description.

Therefore, the spirit of the present invention should not be limited to the described embodiments, and the scope of the patent claims described below as well as all modifications equal or equivalent to the scope of the claims fall within the scope of the spirit of the present invention.

1. A method of diagnosing a vehicle including an electric motor performed in the vehicle, the method comprising:
acquiring a first measurement value for a temperature associated with the electric motor, a second measurement value for a voltage associated with the electric motor, and a third measurement value for a current associated with the electric motor from one or more sensors installed in the electric motor;
calculating a first score for a predetermined diagnostic factor based on the first measurement value;
calculating a second score for the predetermined diagnostic factor based on the second measurement value;
calculating a third score for the predetermined diagnostic factor based on the third measurement value;
reading a weight for each of the temperature, the voltage, and the current with regard to the predetermined diagnostic factor from a database installed in the vehicle; and
calculating a comprehensive diagnostic score for the predetermined diagnostic factor based on the weight for each of the first score, the second score, the third score, and the predetermined diagnostic factor.

2. The method according to claim 1, wherein at least one of the first score, the second score, or the third score is calculated based on at least one of a measurement value, a variance value, and a standard deviation value from a sensor.

3. The method according to claim 1, further comprising updating the weight for the predetermined diagnostic factor at predetermined time intervals.

4. The method according to claim 3, wherein the calculating a comprehensive diagnostic score comprises recalculating the comprehensive diagnostic score in response to weight update.

5. The method according to claim 1, further comprising:
comparing at least one of the first score, the second score, the third score, or the comprehensive diagnostic score calculated for the predetermined diagnostic factor with a corresponding reference value pre-stored in the database; and
generating a warning based on a comparison result.

6. The method according to claim 1, wherein:
the predetermined diagnostic factor is one or more diagnostic factors,
the reading comprises reading three weights for the temperature, the voltage, and the current for each diagnostic factor, and
the calculating comprises calculating the first score, the second score, the third score, and the comprehensive diagnostic score for each diagnostic factor.

7. The method according to claim 1, further comprising evaluating at least one of a state, failure, stability, or expected failure of the electric motor based on the comprehensive diagnostic score.

8. A vehicle diagnostic system installed in a vehicle comprising an electric motor, the vehicle diagnostic system comprising:
a sensor unit comprising a plurality of sensors configured to measure a temperature associated with the electric motor, a voltage associated with the electric motor, and a current associated with the electric motor;
a database configured to store a weight for the temperature, a weight for the voltage, and a weight for the current with regard to a predetermined diagnostic factor; and
one or more processors configured to perform the method according to claim 1.
